(19) United States
(12) Patent Application Publication
(10) Pub. No.: US 2016/0013327 A1
(43) Pub. Date: Jan. 14, 2016

(54) NITRIDE SEMICONDUCTOR DIODE

(71) Applicant: HITACHI, LTD., Chiyoda-ku, Tokyo (JP)

(72) Inventors: Akihisa TERANO, Tokyo (JP); Tomonobu TSUCHIYA, Tokyo (JP); Tsukuru OHTOSHI, Tokyo (JP)

(21) Appl. No.: 14/773,318

(22) PCT Filed: Mar. 8, 2013
(86) PCT No.: PCT/JP2013/056384

§ 371 Date: Sep. 4, 2015

(51) Int. Cl. H01L 29/872; H01L 29/205; H01L 29/20

(52) U.S. Cl. CPC H01L 29/872; H01L 29/2003; H01L 29/205

(57) ABSTRACT

To provide a nitride semiconductor diode that includes conductive layers formed with a two-dimensional electron gas and achieves low on-state resistance characteristics, a high withstand voltage, and low reverse leakage current characteristics, each of the AlGaN layers and the GaN layers in a nitride semiconductor diode including conductive layers of a two-dimensional electron gas that are formed when the AlGaN layers and the GaN layers are alternately stacked has a double-layer structure formed with an undoped layer (upper layer) and an n-type layer (lower layer).

### TECHNICAL FIELD

The present invention relates to a nitride semiconductor diode that includes at least two conductive layers (drift layers) of a two-dimensional electron gas (2DEG) that are formed by stacking nitride semiconductors having different bandgap energies.

### BACKGROUND ART

In recent years, electronic device elements using wide bandgap semiconductors such as SiC and GaN have been actively developed for applications in power electronics.

As for nitride semiconductors such as GaN, lateral devices using undoped AlGaN/GaN heterojunctions are being actively developed.

Characteristically, conductive layers formed with a two-dimensional electron gas (2 Dimensional Electron Gas: hereinafter abbreviated as 2DEG) are formed on the GaN sides near the junction interfaces due to a large band offset and the influence of spontaneous polarization and strong piezoelectric polarization that occur in the heterojunction interfaces. As the 2DEG conductive layers have a high electron mobility and a high electron concentration (on the order of 10¹³ cm⁻²), HEMT (High Electron Mobility Transistor) elements using AlGaN/GaN heterostructures are mounted on high-frequency circuits, and are also mounted as switching elements on DC-DC converter circuits and the like for power electronics products these days.

Horizontal diodes using the above described heterostructures are also being developed for applications in power electronics. So as to improve forward characteristics, AlGaN/GaN heterojunctions are stacked in the vertical direction, for example, to form conductive layers (drift layers) formed with 2DEG in the vertical direction (substrate direction). In this manner, the current density per unit area is increased.

In this aspect, PTL 1 discloses that, in a horizontal diode having multilayer heterojunctions, an anode electrode and a cathode electrode are formed at the side surface portions of the heterojunctions, so that the access resistance to the 2DEG conductive layers located in lower positions can be made lower.

Further, NPL 1 discloses that an anode electrode and a cathode electrode are formed at the side surface portions of three 2DEG conductive layers exposed by semiconductor etching, so that an on-state resistance of 52 mΩcm² and a reverse breakdown voltage of 9400 V are obtained.

### CITATION LIST

### Patent Literature

PTL 1: JP 2009-117485 A

### Non-Patent Literature

NPL 1: T. Ueda et al. Phys. Status Solid B 247, No. 7 (2010)

### SUMMARY OF INVENTION

### Technical Problem

Undoped GaN layers and undoped AlₓGa₁₋ₓN (hereinafter referred to simply as AlGaN layers) disclosed in PTL 1 and NPL 1 are stacked to form two or more 2DEG conductive layers in the vertical direction, and the 2DEG conductive layers are used as the drift layers of the diode. This is an effective technique for lowering the sheet resistance of all the drift layers, lowering the on-state resistance of the horizontal diode, and increasing the current density, as the Ns in the 2DEG conductive layers increases in accordance with the number of 2DEG conductive layers.

In a conventional vertical schottky barrier diode (SBD), a substrate formed by growing an n-type GaN drift layer with a low carrier density on an n-type GaN substrate is used, for example, an anode electrode is formed on the n-type GaN drift layer on the substrate surface side, and a cathode electrode is formed on the back surface of the n-type GaN substrate. In comparison with the vertical SBD in which current is applied to the entire anode electrode surface in contact with the n-type GaN drift layer, current is applied only to extremely thin 2DEG conductive layers in a horizontal diode. With two or three drift layers formed with 2DEG conductive layers, the on-state resistance per unit area is still higher than that of a vertical diode, and sufficient characteristics for realizing large-current drive are not achieved.

So as to lower the on-state resistance of such a horizontal diode to that of a vertical diode, it is effective to widen the bandgap on the barrier layer side at each heterojunction. In the case of AlGaN/GaN heterojunctions, for example, it is effective to increase the sheet carrier density Ns in each 2DEG conductive layer by maximizing the Al composition in the AlGaN barrier layers, and further, maximize the number of 2DEG conductive layers by significantly increasing the number of the heterojunction layers.

However, where AlGaN layers having an Al composition ratio X (hereinafter referred to simply as “Al composition”) increased to 0.2 or higher and GaN layers are alternately stacked so as to increase the number of layers significantly, cracks are formed in the epitaxial layer surface due to the influence of differences in the critical thickness and the thermal expansion coefficient. For example, an epitaxial substrate in which heterojunctions formed with five pairs of an AlGaN layer and a GaN layer (five 2DEG conductive layers) are stacked on a sapphire substrate via a buffer layer was manufactured, the Al composition of the AlGaN layers having being increased to 0.25. When epitaxial growth was completed, a few cracks were observed in the substrate surface. When a horizontal diode was about to be manufactured with this epitaxial substrate, more cracks were formed in the epitaxial layer surface in the initial stage of the test production process.

Therefore, where heterojunctions formed with AlGaN layers with an increased Al composition and GaN layers are stacked in the vertical direction so as to increase the sheet carrier density Ns in each 2DEG conductive layer and lower the on-state resistance in the forward characteristics of a horizontal diode, cracks are formed in the epitaxial surface, and a large-area horizontal nitride semiconductor diode that is capable of large-current driving cannot be manufactured.

The present invention aims to provide a nitride semiconductor diode that includes at least two conductive layers (drift layers) that are formed with a two-dimensional electron gas (2DEG) by stacking nitride semiconductors having different bandgap energies, such as GaN and AlGaN. This nitride semiconductor diode can increase its area without any cracks formed in the epitaxial layer surface, and lower the on-state resistance in forward characteristics of the diode.

### Solution to Problem

Typical embodiments of the present application are described below.

A nitride semiconductor diode including:

a substrate;

a nitride semiconductor film stack formed on the substrate by alternately stacking layers made of GaN as lower layers and layers made of AlGaN as upper layers, the nitride semiconductor film stack including conductive layers formed with a two-dimensional electron gas generated on the lower layer sides of heterojunction interfaces between the lower layers and the upper layers;

a recess formed in part of the nitride semiconductor film stack;

a cathode electrode in contact with part of the nitride semiconductor film stack, the cathode electrode being ohmically connected to the conductive layers formed with the two-dimensional electron gas; and

an anode electrode schottky-connected to a side surface of the nitride semiconductor film stack, the side surface of the nitride semiconductor film stack including side surfaces of the conductive layers formed with the two-dimensional electron gas, the side surfaces of the conductive layers being exposed through the recess,

wherein

the conductive layers formed with the two-dimensional electron gas function as drift layers,

each of the layers made of AlGaN has a first stack structure formed with an n-type AlGaN layer having n-type conductivity with an impurity added thereto, and an undoped AlGaN layer not having an impurity added thereto, and,

in each of the layers made of AlGaN and formed with the first stack structures, the n-type AlGaN layer is located in a lower position than the undoped AlGaN layer.

A nitride semiconductor diode including:

a substrate;

a nitride semiconductor film stack formed on the substrate by alternately stacking layers made of GaN as lower layers and layers made of AlGaN as upper layers, the nitride semiconductor film stack including conductive layers formed with a two-dimensional electron gas generated on the lower layer sides of heterojunction interfaces between the lower layers and the upper layers;

a recess formed in part of the nitride semiconductor film stack;

a cathode electrode in contact with part of the nitride semiconductor film stack, the cathode electrode being ohmically connected to the conductive layers formed with the two-dimensional electron gas; and

an anode electrode schottky-connected to a side surface of the nitride semiconductor film stack, the side surface of the nitride semiconductor film stack including side surfaces of the conductive layers formed with the two-dimensional electron gas, the side surfaces of the conductive layers being exposed through the recess,

wherein

the conductive layers formed with the two-dimensional electron gas function as drift layers,

each of the layers made of GaN has a second stack structure formed with an n-type GaN layer having n-type conductivity with an impurity added thereto, and an undoped GaN layer not having an impurity added thereto, and,

in each of the layers made of GaN and formed with the second stack structures, the n-type GaN layer is located in a lower position than the undoped GaN layer.

In a nitride semiconductor diode, the layers made of GaN and formed with the second stack structures, and the layers made of AlGaN and formed with the first stack structures are alternately stacked.

### Advantageous Effects of Invention

With a structure according to the present invention, it is possible to provide a nitride semiconductor diode that includes at least two conductive layers (drift layers) that are formed with a two-dimensional electron gas (2DEG) when nitride semiconductors having different bandgap energies, such as GaN and AlGaN, are stacked. This nitride semiconductor diode lowers the on-state resistance in forward characteristics, and achieves low-leakage and high-withstand-voltage characteristics in reverse characteristics, without any cracks formed in the epitaxial layer surface.

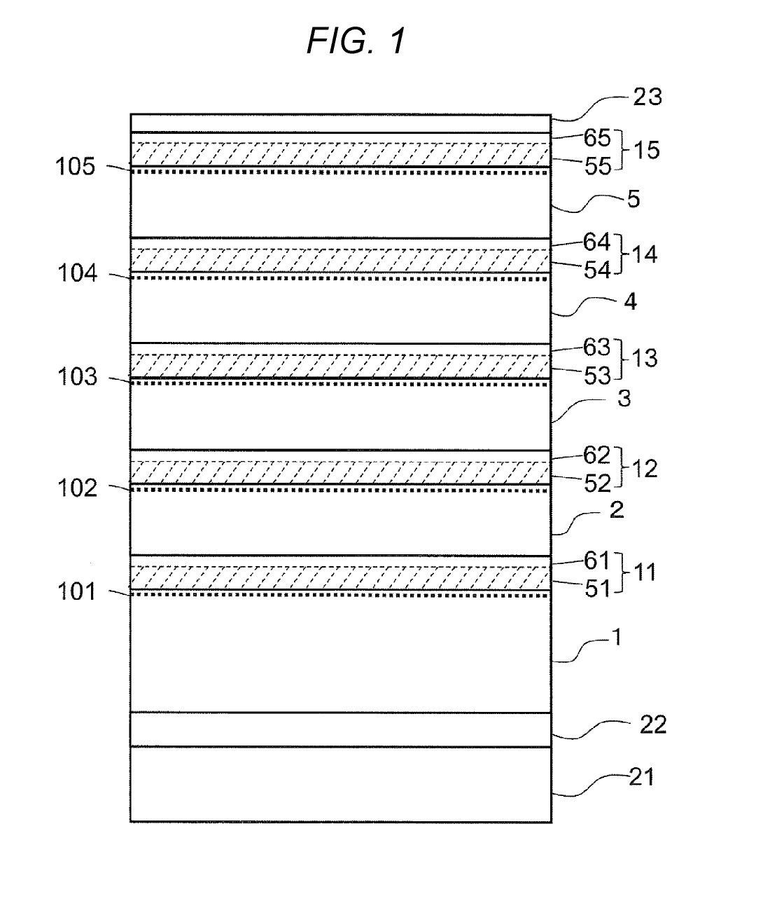

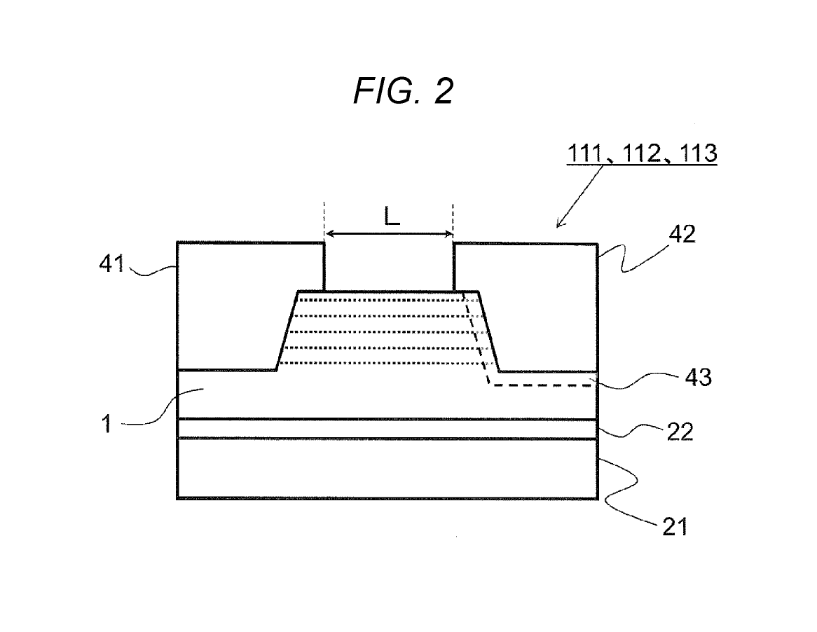

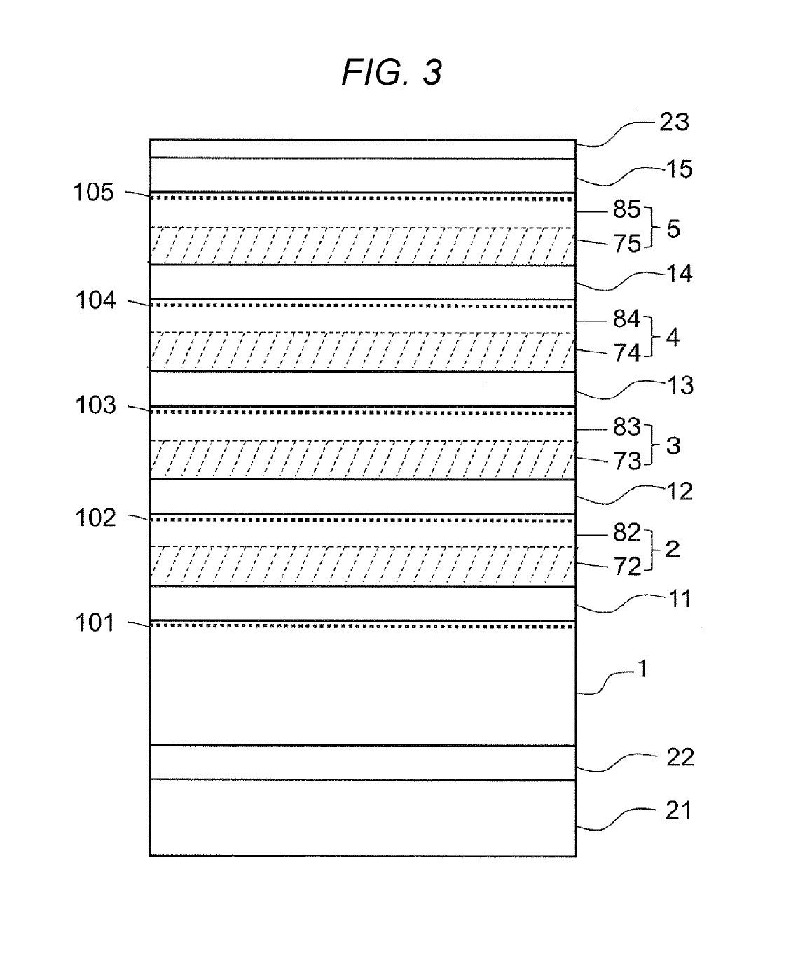

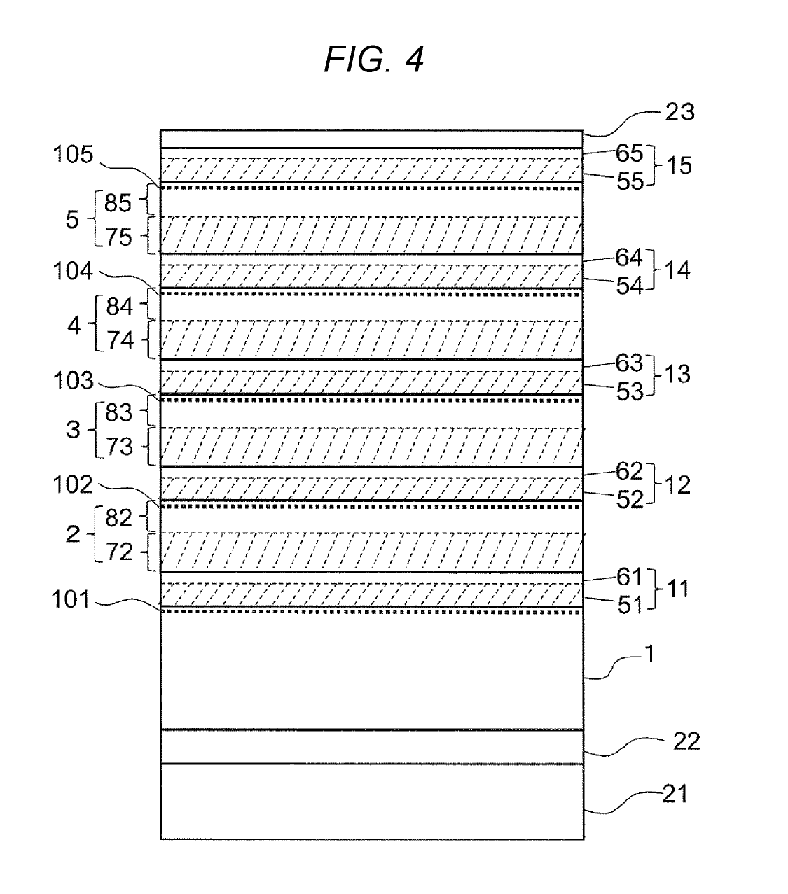

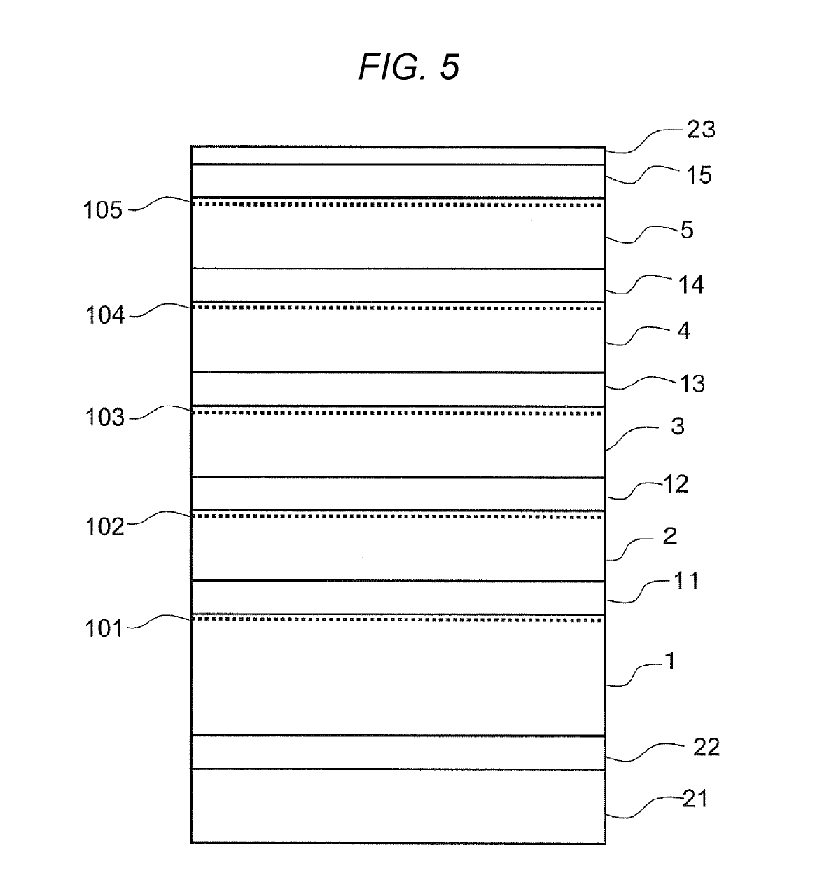

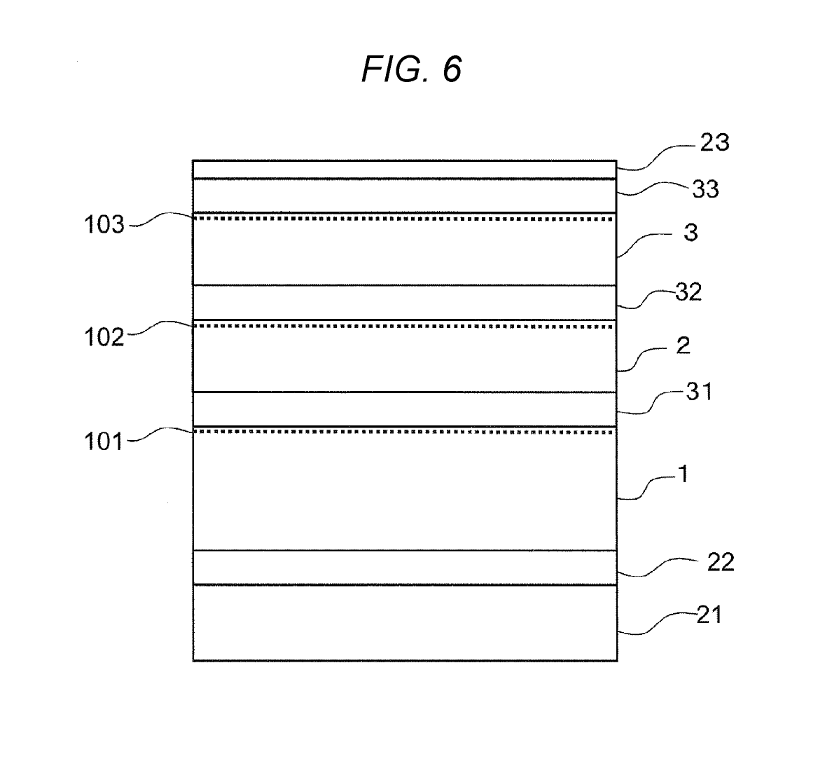

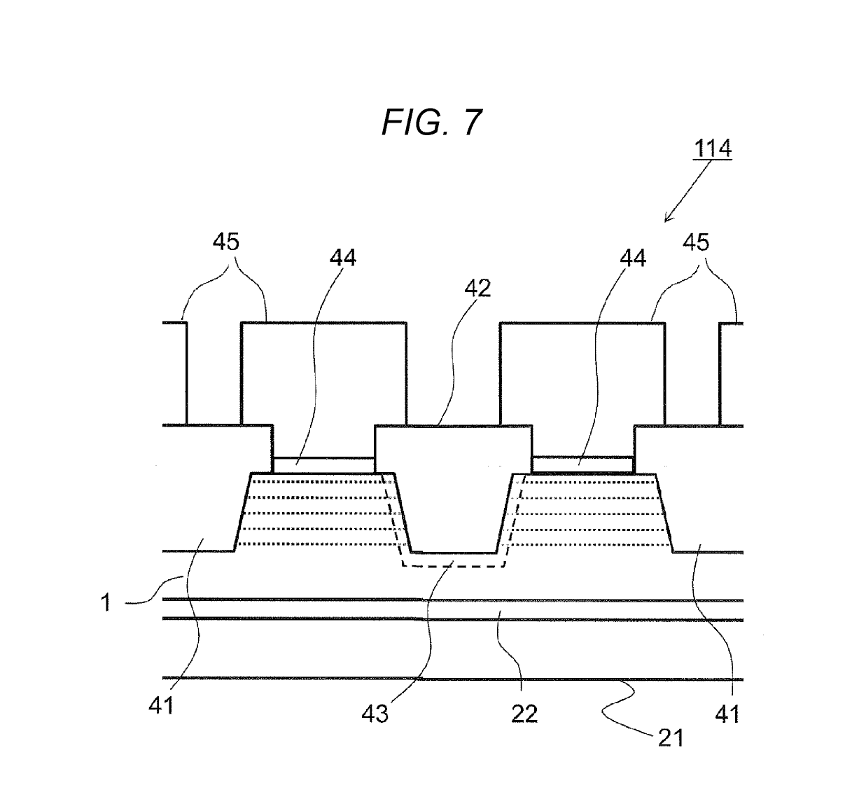

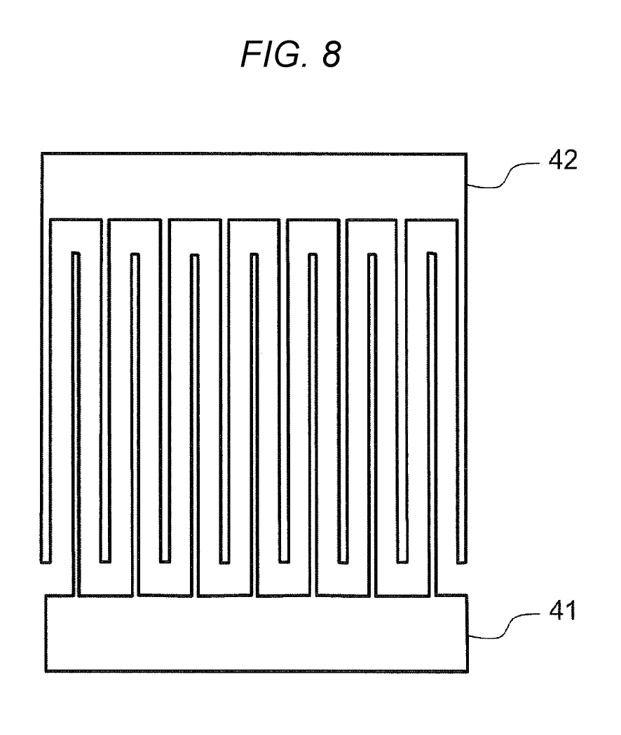

### BRIEF DESCRIPTION OF DRAWINGS

[FIG. 1] FIG. 1 is a cross-sectional diagram showing the epitaxial structure of an epitaxial substrate used in a first embodiment of the present invention.

[FIG. 2] FIG. 2 is a schematic cross-sectional diagram showing part of the principal region in a nitride semiconductor diode of first through third embodiments of the present invention.

[FIG. 3] FIG. 3 is a cross-sectional diagram showing the epitaxial structure of an epitaxial substrate used in the second embodiment of the present invention.

[FIG. 4] FIG. 4 is a cross-sectional diagram showing the epitaxial structure of an epitaxial substrate used in the third embodiment of the present invention.

[FIG. 5] FIG. 5 is a cross-sectional diagram showing the epitaxial structure of an epitaxial substrate that includes five 2DEG conductive layers formed with conventional structures, and was used in a comparative experiment in the present invention.

[FIG. 6] FIG. 6 is a cross-sectional diagram showing the epitaxial structure of an epitaxial substrate that includes three 2DEG conductive layers formed with conventional structures, and was used in a comparative experiment in the present invention.

[FIG. 7] FIG. 7 is a cross-sectional diagram showing part of the principal region in a large-area diode of a fourth embodiment of the present invention.

[FIG. 8] FIG. 8 is a diagram schematically showing the layout in which an anode electrode and a cathode electrode of the fourth embodiment of the present invention are placed to face each other.

### DESCRIPTION OF EMBODIMENTS

First, the results of a study made by the inventors are described.

As described above, in an epitaxial substrate including five 2DEG conductive layers formed by alternately stacking AlGaN layers having an Al composition of 0.25 and GaN layers, cracks were formed in the surface when epitaxial growth finished. In view of this, five kinds of structures each including five 2DEG conductive layers with AlGaN layers having Al compositions of 0.1, 0.13, 0.17, 0.2, and 0.23 were manufactured, and a check was made to determine whether cracks were formed in the surfaces of the epitaxial substrates after completion of epitaxial growth. The basic structure of each of the manufactured epitaxial substrates is shown in FIG. 5.

Specifically, an epitaxial structure is formed with a stack structure that includes, from the bottom, a first GaN layer 1 formed with an undoped layer having a thickness of 3.0 μm, a first AlGaN layer 11 formed with an undoped layer having a thickness of 25 nm, a second GaN layer 2 formed with an undoped layer having a thickness of 100 nm, a second AlGaN layer 12 formed with an undoped layer having a thickness of 25 nm, a third GaN layer 3 formed with an undoped layer having a thickness of 100 nm, a third AlGaN layer 13 formed with an undoped layer having a thickness of 25 nm, a fourth GaN layer 4 formed with an undoped layer having a thickness of 100 nm, a fourth AlGaN 14 layer formed with an undoped layer having a thickness of 25 nm, a fifth GaN layer 5 formed with an undoped layer having a thickness of 100 nm, a fifth AlGaN layer 15 formed with an undoped layer having a thickness of 25 nm, and an undoped GaN cap layer 23 having a thickness of 5 nm, which are formed on a sapphire substrate 21 via a low-temperature buffer layer 22. In the first through fifth undoped GaN layers, first through fifth 2DEG conductive layers 101 through 105 are formed on the respective GaN layer side of heterojunction interfaces having the first through fifth undoped AlGaN layers provided on the upper surfaces thereof.

In this experiment, the five types of epitaxial substrates having the first through fifth AlGaN layers with different Al compositions were manufactured by a known MOVPE (Metal Organic Vapor Phase Epitaxy) method. Among the five types of manufactured epitaxial substrates including AlGaN layers with different Al compositions, no cracks were observed in the epitaxial surfaces of the epitaxial substrates with Al compositions of 0.1 to 0.2, but cracks were formed in the epitaxial surface of the epitaxial substrate with the Al composition of 0.23 as in the above described case where the Al composition was 0.25. As shown in FIG. 6, an epitaxial substrate including three 2DEG conductive layers formed by alternately stacking first through third undoped AlGaN layers 31 through 33 having an Al composition of 0.25 and first through third GaN layers 1 through 3 formed with undoped layers was also manufactured. However, no cracks were observed in the surface when epitaxial growth finished, and a diode was completed without any cracks formed during the processing for the test diode

It is known that, in a case where AlGaN layers having different lattice constants are epitaxially grown on GaN layers, cracks are formed when a certain critical thickness is exceeded. As the Al composition of the AlGaN layers becomes higher, the differences in lattice constant and thermal expansion coefficient from GaN become larger.

Through the above described study made by the inventors, it became apparent that, where AlGaN layers (25 nm in thickness) having an Al composition of 0.25 and GaN layers (100 nm in thickness) were alternately stacked, cracks were formed in the epitaxial surface when five 2DEG conductive layer were stacked. However, the inventors found that cracks were not formed when the number of 2DEG conductive layers was reduced to three.

The sheet carrier densities Ns in the 2DEG conductive layers in multilayer structures each formed with the five 2DEG conductive layers shown in FIG. 5 were calculated through a simulated calculation in a case where the Al composition of the AlGaN layers having no cracks formed therein was 0.2 and in a case where the Al composition of the AlGaN layers having cracks formed therein was 0.25. The results of the calculation show that the total Ns in the five 2DEG conductive layers in the case where the Al composition was 0.2 was approximately 1.4×10¹³ cm⁻², and the total Ns in the five 2DEG conductive layers in the case where the Al composition was 0.25 was approximately 2.6×10¹³ cm⁻², which is almost twice the Ns value obtained in the case where the Al composition was 0.2.

Also, the results of calculation of the Ns values of the respective 2DEG conductive layers show that the highest Ns was obtained in the fifth 2DEG conductive layer as the uppermost epitaxial layer, and the second highest Ns was obtained in the first 2DEG conductive layer as the lowermost 2DEG conductive layer. The Ns in all the three layers of the second through fourth 2DEG conductive layers located between the fifth and first 2DEG conductive layers had the same Ns value, which is the lowest value among the five 2DEG conductive layers.

In the cases where the Al compositions of the AlGaN layers were 0.2 and 0.25, which are relatively high, the Ns in each of the first through fifth 2DEG conductive layers was higher than 1×10¹² cm⁻². In a case where the Al compositions of those layers were reduced to 0.15, however, the Ns in each of the second through fourth 2DEG conductive layers was lower than 1×10¹¹ cm⁻². Therefore, it can be said that, if the Al compositions of the AlGaN layers are too low, the second through fourth 2DEG conductive layers hardly contribute to an increase in the total Ns.

The total Ns in the five 2DEG conductive layers in the case where the Al compositions were 0.15 was almost 5×10¹² cm⁻², which is lower than the Ns value 1.0×10¹³ cm⁻²) of a conventional HEMT epitaxial substrate having a single-layer 2DEG conductive layer with an Al composition of 0.25, for example, in spite of the five 2DEG conductive layers.

So as to compare the electrical characteristics of actual epitaxial substrates with the above simulation results, the inventors next manufactured three types of epitaxial substrates including five 2DEG conductive layers with the AlGaN layers having the structure shown in FIG. 5 and the three Al compositions of 0.25, 0.2, and 0.15, and measured the Hall effects.

After the manufacture of the epitaxial substrates, each of the epitaxial substrate was cut into a 5 mm square by dicing so as to produce a Hall element. In the substrate surface of an epitaxial substrate with the AlGaN layers having the Al composition of 0.25 in this stage, so many cracks were formed that characterization could not be performed. In the epitaxial substrates with the corresponding layers having the Al compositions of 0.2 and 0.15, on the other hand, no cracks by dicing were observed. The results of Hall effect measurement carried out on five samples of each of the two epitaxial substrates without any cracks show that the Ns in an epitaxial substrate having the Al composition of 0.2 was in the range of 1.34×10¹³ cm⁻² to 1.41×10¹³ cm⁻², and characteristics substantially the same as those of the above described calculation results were obtained.

As for an epitaxial substrate having the Al composition of 0.15, the Ns was in the range of 4.22×10¹² cm⁻² to 4.87×10¹² cm⁻², and characteristics that were almost the same as those of the simulation results were achieved.

In view of the above, in order to lower the on-state resistance of a horizontal diode including drift layers that are the 2DEG conductive layers generated through the heterojunctions between AlGaN layers and GaN layers, AlGaN layers with an increased Al composition and GaN layers are alternately stacked in the vertical direction so that the number of 2DEG conductive layers is effectively and ideally creased.

According to the study by the inventors, however, where AlGaN layers and GaN layers are alternately stacked, the cracks formed in the epitaxial layer surface supposedly due to the differences in lattice constant and thermal expansion coefficient between the AlGaN layers and the GaN layers increase, as the Al composition of the AlGaN layers becomes higher. Therefore, the number of stacked layers needs to be reduced as the Al composition becomes higher. This is also apparent from a comparison between the crack formation in the above described epitaxial substrate including three 2DEG conductive layers and the crack formation in an epitaxial substrate including five 2DEG conductive layers.

Therefore, in increasing the number of 2DEG conductive layers while reducing cracks formed in the epitaxial surface, it is effective to reduce the Al composition in each AlGaN layer or reduce the thickness of each AlGaN layer. According to the study by the inventors, however, the effect of an increase in the number of 2DEG conductive layers tends to become smaller, as the Al composition becomes lower, as described above.

It is also known that, when the thickness of the each AlGaN layer is reduced, the effect of polarization in the heterointerfaces becomes smaller, and therefore, the Ns in each 2DEG conductive layer tends to become lower.

In the study by the inventors, when the thickness of each AlGaN layer having an Al composition of 0.25 was reduced to 15 nm or smaller, the Ns became almost one digit lower than that obtained when the thickness of each AlGaN layer was 25 nm. In view of this, the thickness of each AlGaN layer is preferably at least 15 nm or greater, and more preferably, 20 nm or greater.

Cracks are easily formed if each AlGaN layer is too thick. Therefore, the upper limit of the thickness of each AlGaN layer is preferably not greater than necessary.

Even if the thickness of each AlGaN layer is made greater than a certain value, the Ns in each 2DEG conductive layer hardly differs from the Ns obtained with a reasonable AlGaN layer thickness. Therefore, the upper limit of the thickness of each AlGaN layer in a multilayer structure formed by alternately stacking AlGaN layers and GaN layers is approximately 40 nm, and more preferably, each AlGaN layer is thinner than 30 nm, so as to reduce cracks.

In the second through fifth GaN layers on and under which AlGaN layers are provided as shown in FIG. 7, for example, 2DEG conductive layers are formed on the GaN layer sides near the heterojunction interfaces with the AlGaN layers provided on the upper surfaces of the respective GaN layers. The Ns in each 2DEG conductive layer also changes with the thickness of each of these GaN layers. According to the study by the inventors, the Ns tends to rapidly become lower as the thickness of each GaN layer becomes lower after becoming lower than 50 nm. In a case where each GaN layer is thicker than 50 nm, on the other hand, the Ns of course becomes higher as the thickness becomes greater. However, the changes are much smaller than the changes caused when the thickness is made smaller than 50 nm.

Therefore, the thickness of each of the GaN layers on and under which AlGaN layers are provided as described above is preferably at least greater than 50 nm, and more preferably, greater than 70 nm.

In the above described structure, the Ns obtained when the GaN layer thickness is greater than 300 nm is not much different from the Ns obtained when the GaN layer thickness is 3 μm. Therefore, it can be said that, if the upper limit of the thickness of each GaN layer in the above described structure is too great, the effect on the increase in Ns is small.

Further, in a case where a stack structure including five 2DEG conductive layers is manufactured with the thickness of each GaN layer being on the order of micrometers, for example, 5 μm or larger etching needs to be performed on the semiconductor layers so as to expose all the 2DEG side surface portions on which the anode electrode is to be formed. In the process of manufacturing a diode, this is not realistic due to an increase in the etching amount difference caused by an in-plane distribution and a decrease in throughput.

Therefore, the thickness of each GaN layer in the above described structure is preferably smaller than 300 nm in the manufacturing process as described above, and is preferably greater than 50 nm so as to lower the on-state resistance of the diode.

The above described ranges are the preferable ranges of the thicknesses of AlGaN layers and GaN layers to form 2DEG conductive layers by alternately stacking conventional AlGaN layers and GaN layers, with the problems related to the Al composition of AlGaN layers being eliminated.

As is apparent from the above explanation, it is assumed that there is almost a trade-off relationship between the Al composition of the AlGaN layers and the number of 2DEG conductive layers. Therefore, in the case of a stack structure using AlGaN layers formed with conventional undoped layers and GaN layers formed with undoped layers, if AlGaN layers having a high Al composition are used, the Ns in each 2DEG conductive layer can be made higher. However, cracks are more easily formed due to an increase in the number of layers, and the number of 2DEG conductive layers cannot be increased. If AlGaN layers having a low Al composition are used, on the other hand, cracks are not easily formed, and the number of 2DEG conductive layers can be increased. In that case, however, the Ns in each 2DEG conductive layer becomes lower. In view of the above, it is assumed that there is a limit to the decrease in the on-state resistance of a horizontal diode, as long as a stack structure formed with conventional undoped layers is used.

The present invention aims to realize an epitaxial structure that can increase the sheet carrier density Ns in each 2DEG conductive layer without any cracks formed in the epitaxial layer surface even if the number of layers is increased in a nitride semiconductor diode that includes drift layers formed with two or more 2DEG conductive layers that are formed in the heterojunction interfaces by alternately stacking AlGaN layers and GaN layers in the above described thickness ranges. Specifically, it is necessary to realize a structure that can increase the Ns in each 2DEG conductive layer even when the Al composition of each AlGaN layer in the film stack is lowered so as to reduce cracks due to alternate stacking of AlGaN layers and GaN layers.

To counter this problem, the inventors made an intensive study, and discovered that, where each AlGaN layer or each GaN layer, or each of the AlGaN layers and the GaN layers is a stack structure formed with an n-type doped layer (lower layer) and an undoped layer (upper layer), the Ns in each 2DEG conductive layer can be made higher even when the Al composition of each AlGaN layer is lowered, and furthermore, the Ns in each 2DEG conductive layer can be controlled to be a desired value. Further, with the use of an epitaxial substrate manufactured with a structure according to the present invention, it is possible to provide a nitride semiconductor diode that has a low forward on-state resistance and excellent reverse characteristics.

The following is a description of embodiments and effects of the present invention, with reference to the drawings.

### First Embodiment

In the description below, an embodiment of a nitride semiconductor diode as a first embodiment of the present invention is explained.

FIG. 1 is a cross-sectional view of an epitaxial structure including five 2DEG conductive layers according to this embodiment. FIG. 2 is a cross-sectional diagram showing part of the principal region of the nitride semiconductor diode as the first embodiment of the present invention manufactured by using an epitaxial substrate having the epitaxial structure shown in FIG. 1.

In FIG. 2, to avoid complexity of the drawing, the stack structure formed with AlGaN layers and GaN layers is not shown, and only the five 2DEG conductive layers are shown by dashed lines.

To facilitate a comparison with a conventional structure, the nitride semiconductor diode of the first embodiment according to the present invention includes drift layers formed with five 2DEG conductive layers like the above described epitaxial structure shown in FIG. 5, and only the thickness of the uppermost GaN cap layer is 10 nm.

As shown in FIG. 1, one of the features of the present invention lies in that the five layers of first through fifth AlGaN layers 11 through 15 have double-layer structures that are formed with first through fifth n-type AlGaN layers 51 through 55 that are formed in the lower regions, have Si added thereto as an n-type impurity, have a Si doping concentration of 2×10¹⁷ cm⁻³, have a thickness of 20 nm, and have an Al composition of 0.17, and first through fifth undoped AlGaN layers 61 through 65 that are formed in the upper regions, have the same Al composition as above, and have a thickness of 5 nm.

The total Ns in 2DEG conductive layers 101 through 105 of this epitaxial structure (FIG. 1) as an embodiment of the present invention, in which the thickness of second through fifth GaN layers 2 through 5 formed with undoped layers is 100 nm, is approximately 1.5×10¹³ cm⁻², which is close to the total Ns in the five 2DEG conductive layers formed with stack structures including only conventional undoped layers with an Al composition of 0.25. According to a simulated calculation, the Ns in each 2DEG conductive layer formed with the above described epitaxial structure of the present invention is 1.5×10¹² cm⁻² to 5.0×10¹² cm⁻². Although the Al composition of the AlGaN layers is lowered to 0.17, the Ns in each 2DEG conductive layer is relatively high.

In the nitride semiconductor diode 111 (shown in FIG. 2) manufactured with an epitaxial substrate having the epitaxial structure shown in FIG. 1, an anode electrode 41 is formed on side surfaces of the five 2DEG conductive layers as shown in the drawing, and a cathode electrode 42 is formed on the other side surfaces of the 2DEG conductive layers on the opposite side of the 2DEG conductive layers from the anode electrode 41 as shown in the drawing. On the 2DEG side surface portions having the cathode electrode 42 formed thereon, a region 43 turned into an n-type region through Si ion implantation is formed, and the ohmic contact between the cathode electrode 42 and each of the 2DEG conductive layers 101 through 105 is improved with this region 43.

In the nitride semiconductor diode as the first embodiment of the present invention, the distance L between the anode electrode 41 and the cathode electrode 42 was set at 20 μm in manufacturing a test nitride semiconductor diode, and the on-state resistance per unit facing width (1 mm) was determined from the forward characteristics, to obtain a value of approximately 20 Ω. Further, the results of evaluation of the reverse characteristics showed that the breakdown voltage was 600 to 700 V, and the leakage current was 1.0×10⁻⁶ A/mm or lower until after breakdown. The characteristics depend on the Ns value, the Si doping concentration in the n-type AlGaN layer, and the thickness of each of the five 2DEG conductive layers.

According to the study by the inventors, if the Ns in each 2DEG conductive layer is 8×10¹² cm ⁻² or higher, the ratio between forward current and reverse current of the diode becomes a five-digit number or smaller, which is not preferable in terms of operation of the diode.

Therefore, in a structure including a number of 2DEG conductive layers as in the present invention, the Ns in each 2DEG conductive layer is preferably 8×10¹²cm⁻²at the highest, and more preferably, needs to be set and adjusted to a lower value than the above Ns value.

As the lower limit of the Ns value becomes lower, the reverse leakage current becomes lower, but the on-state resistance becomes higher as much, as described above. So as to lower the on-state resistance, the total Ns in the 2DEG conductive layers needs to be increased. Therefore, the Ns is preferably 1×10¹² cm⁻² or higher at the lowest.

So as to obtain a desired Ns in each 2DEG conductive layer, the Si doping concentration in the n-type layer in each AlGaN layer having a double-layer structure formed with an undoped layer and the n-type layer of the present invention is preferably set in the range of 5×10¹⁶ cm⁻³ (inclusive) to 5×10¹⁷ cm⁻³ (inclusive).

In a case where the Si doping concentration is lower than 5×10¹⁶ cm⁻³ in an AlGaN layer having a thickness of 30 nm or smaller, which is suitable for forming a multilayer structure, the effect to increase the Ns in each 2DEG conductive layer becomes noticeably smaller. In a case where the Si doping concentration is higher than 5×10¹⁷ cm⁻³, the schottky characteristics of the anode electrode are degraded, and the reverse leakage current noticeably increases.

Also, the thickness of each n-type AlGaN layer is preferably equal to or greater than 50% of the thickness of the entire corresponding AlGaN layer. If the thickness of each n-type AlGaN layer is smaller than that, the effect to increase the Ns in each 2DEG conductive layer becomes noticeably smaller like the above mentioned Si doping concentration.

### Second Embodiment

An embodiment of a nitride semiconductor diode as a second embodiment of the present invention is now described.

FIG. 3 is a cross-sectional view of an epitaxial structure including five 2DEG conductive layers according to this embodiment. A cross-sectional diagram showing part of the principal region of the nitride semiconductor diode of this embodiment should be the same as that shown in FIG. 2.

To facilitate a comparison with a conventional structure, the epitaxial structure and the nitride semiconductor diode of the second embodiment according to the present invention include drift layers formed with five 2DEG conductive layers like the above described epitaxial structure shown in FIG. 1. As shown in FIG. 3, one of the features of the present invention lies in that second through fifth GaN layers 2 through 5 each having thickness of 100 nm have double-layer structures that are formed with second through fifth n-type GaN layers 72 through 75 that are formed in the lower regions, have Si added thereto as an n-type impurity, have a Si doping concentration of 1×10¹⁷ cm⁻³, and have a thickness of 50 nm, and second through fifth undoped GaN layers 82 through 85 that are formed in the upper regions and have a thickness of 50 nm.

The total Ns in 2DEG conductive layers of this epitaxial structure (FIG. 3) as the second embodiment of the present invention, in which the thickness of each of first through fifth AlGaN layers 11 through 15 formed with undoped layers is 25 nm, is approximately 2.0×10¹³ cm⁻² in actual measured value, which is also substantially the same as the total Ns in the five 2DEG conductive layers formed with stack structures including only conventional undoped layers with an Al composition of 0.25.

In the nitride semiconductor diode 112 as the second embodiment of the present invention that was manufactured with an epitaxial substrate having the epitaxial structure shown in FIG. 3 and has a cross-section structure having the principal region shown in FIG. 2, the distance L between the anode electrode 41 and the cathode electrode 42 was set at 40 μm in manufacturing the test nitride semiconductor diode 112, and the reverse characteristics were evaluated. As a result, high withstand voltage characteristics with a breakdown voltage of 1.5 kV or higher were obtained, and the leakage current was 1.5×10⁻⁶ A/mm or lower as in the above described nitride semiconductor diode shown in FIG. 2.

Also, the on-state resistance per unit facing width (1 mm) was determined from the forward characteristics, to obtain a low value of approximately 18 Ω.

In a case where the lower region in each GaN layer is an n-type doped layer as in the present invention, the thickness of the n-type layer is preferably equal to or greater than 10 nm, and more preferably, greater than 20 nm. However, it is not preferable to perform Si doping on the upper region in each GaN layer in which a 2DEG conductive layer is formed. This is because the electron mobility in the 2DEG generation region becomes lower due to the influence of impurity scattering. Also, the Si doping concentration in the n-type layer in the above described GaN layer is preferably 5×10¹⁶ cm ⁻³ (inclusive) to 5×10¹⁷ cm⁻³ (inclusive).

In a case where the Si doping concentration is lower than 5×10¹⁶ cm⁻³, an increase in the proportion of the thickness of the n-type layer in the entire GaN layer hardly contributes to an increase in the Ns in the corresponding 2DEG conductive layer.

### Third Embodiment

An embodiment of a nitride semiconductor diode as a third embodiment of the present invention is now described. FIG. 4 is a cross-sectional view of an epitaxial structure including five 2DEG conductive layers according to this embodiment. A cross-sectional diagram showing part of the principal region of the nitride semiconductor diode of this embodiment should be the same as that shown in FIG. 2.

To facilitate a comparison with a conventional structure, the epitaxial structure and the nitride semiconductor diode of the third embodiment according to the present invention include drift layers formed with five 2DEG conductive layers like the above described epitaxial structures shown in FIGS. 1 and 2.

In this embodiment of the present invention, Si doping is performed on the lower regions of first through fifth AlGaN layers 11 through 15 formed with five 25-nm thick films as shown in FIG. 4, and the lower regions of second through fifth 100-nm thick GaN layers 2 through 5 on and under which AlGaN layers are formed. The five layers of the first through fifth AlGaN layers 11 through 15 have double-layer structures that are formed with first through fifth n-type AlGaN layers 51 through 55 that are formed in the lower regions, have Si added thereto as an n-type impurity, have a Si doping concentration of 8×10¹⁶ cm⁻³, have a thickness of 20 nm, and have an Al composition of 0.20, and first through fifth undoped AlGaN layers 61 through 65 that are formed in the upper regions, have the same Al composition as above, and have a thickness of 5 nm.

The second through fifth GaN layers 2 through 5 each having a thickness of 100 nm have double-layer structures that are formed with second through fifth n-type GaN layers 72 through 75 that are formed in the lower regions, have Si added thereto as an n-type impurity, have a Si doping concentration of 5×10¹⁶ cm⁻³, and have a thickness of 50 nm, and second through fifth undoped GaN layers 82 through 85 that are formed in the upper regions and have a thickness of 50 nm.

The structure of the nitride semiconductor diode shown in FIG. 6 manufactured with an epitaxial substrate having the epitaxial structure shown in FIG. 5 is the same as the above described structures shown in FIGS. 2 and 4, except for the epitaxial substrate.

In the nitride semiconductor diode 113 as the third embodiment of the present invention, the distance between the anode electrode 41 and the cathode electrode 42 was set at 50 μm in manufacturing the test diode, and the reverse characteristics were evaluated. As a result, high withstand voltage characteristics with a breakdown voltage of 1.5 kV or higher were obtained, and low leakage characteristics with a leakage current of 5.0×10⁻⁶ A/mm or lower were obtained.

Also, the on-state resistance per unit facing width (1 mm) was determined from the forward characteristics, to obtain a low value of approximately 10 Ω.

### Fourth Embodiment

An embodiment of a nitride semiconductor diode as a fourth embodiment of the present invention is now described.

In the fourth embodiment according to the present invention, a test large-area diode 114 having a comb-like anode/cathode facing region in which the element size was 3 mm×3 mm (the active region being 3 mm×2 mm) was manufactured with the epitaxial substrate shown in FIG. 4.

The distance between the anode electrode 41 and the cathode electrode 42 was set at 20 μm, and the electrode metal widths of the anode electrode and the cathode electrode each having a comb-like elongated shape were 20 μm (2 mm in the longitudinal direction). Accordingly, the anode-cathode facing width was approximately 150 mm. A Pd/Au electrode was used as the anode electrode 41, and a Ti/Al electrode was used as the cathode electrode 42. So as to reduce the interconnection resistance components of the electrode metals, the thicknesses of both the Au film and the Al film were set at 5 μm.

The exposed nitride semiconductor surface, except for the anode electrode and the cathode electrode, is protected by a SiN film 44 having a thickness of 200 nm, and the region other than the electrode pads, and the SiN film are covered with a thick polyimide film 45. FIG. 7 is a cross-sectional diagram showing part of the principal region of the manufactured large-area diode 114. FIG. 8 is a diagram schematically showing the layout of the comb-like anode electrode 41 and the comb-like cathode electrode 42.

In FIG. 7, only the five 2DEG conductive layers are shown in each nitride semiconductor region, for the same reason as that mentioned with reference to FIG. 2 of the first embodiment. The forward characteristics of the completed large-area diode 114 were evaluated. As a result, it was confirmed that low on-state resistance characteristics with an on-state resistance of approximately 10 mΩcm², which matched that of a conventional vertical SBD, were obtained, and, with this element size, it was possible to apply a current up to 20 A in the forward direction.

Further, the reverse characteristics were evaluated, to obtain excellent results showing a breakdown voltage of 600 V or higher, and a leakage current level of 2.0×10⁻⁴ A or lower at 600 V, which is five or more digit better as the forward/reverse current ratio.

In all of the above described embodiments, the number of 2DEG conductive layers obtained by alternately stacking AlGaN layers and GaN layers is five, and each of the AlGaN layers and/or GaN layers has a double-layer structure formed with an undoped layer and an n-type layer, the lower regions of the AlGaN layers and/or the GaN layers being doped with Si. However, the present invention is not limited to that. For example, the number of 2DEG conductive layers may be two or more, such as 10, and the Al composition range of the AlGaN layers is not particularly specified when the AlGaN layers and the GaN layers are alternately stacked. As long as AlGaN layers having an appropriate Al composition for the number of stacked layers, and no cracks are formed in the epitaxial surface, double-layer structures each formed with an undoped layer and an n-type layer of the present invention may be used in a stack structure, regardless of the number of 2DEG conductive layers formed in the stack structure. The effects of the present invention is of course achieved in that case. This means that, if the number of 2DEG conductive layers is small, the Al composition of the AlGaN layers can be made higher, and, if the number of 2DEG conductive layers is large, the Al composition is made lower. In that manner, the number of 2DEG conductive layers can be changed through Al composition adjustment in the AlGaN layers, without any cracks formed in the epitaxial surface. In addition to that, with the use of structures according to the present invention, the Ns in each 2DEG conductive layer can be readily adjusted, which is highly advantageous.

At this point, attention should be paid to the fact that the Ns in each 2DEG conductive layer is preferably 1×10¹² cm⁻² or higher at the lowest, and is preferably 8×10¹² cm⁻² at the highest.

Also, the thickness of each AlGaN layer is preferably 15 to 30 nm, and the thickness of each GaN layer on and under which AlGaN layers are provided is preferably 50 to 300 nm.

Although the five AlGaN layers have the same Al composition in each of the above described embodiments of the present invention, the five AlGaN layers do not need to have the same Al composition, and the respective AlGaN layers may have different Al compositions as long as no cracks are formed.

Although a sapphire substrate is used as the substrate in each of the above described embodiments, it is possible to use a SiC substrate, a Si substrate, or a GaN substrate.

Also, in each of the above described embodiments of the present invention, a region that is turned into an n-type region through Si ion implantation is provided on a side surface of a semiconductor stack structure in the region on which the cathode electrode is formed. However, Si-doped regions are provided in the AlGaN layers and the GaN layers in the present invention. Accordingly, even without the n-type region formed through Si ion implantation, a structure according to the present invention has a greater effect to improve the ohmic contact with the 2DEG conductive layers than a conventional stack structure formed only with undoped layers.

Although a SiN film is used as the protection film on the semiconductor surface in the fourth embodiment, the protection film is not necessarily a SiN film, and it is of course possible to use some other insulating film material, such as SiO2, PSG, or Al2O3, in manufacturing a conventional semiconductor element.

As is apparent from the above description, a region turned into an n-type region is preferably provided on part of a side surface portion of the nitride semiconductor film stack with which a cathode electrode is brought into contact in the nitride semiconductor diode of any of the above described embodiments.

Also, in the nitride semiconductor diode of any of the above described embodiments, no impurities are preferably added to the regions in which a two-dimensional electron gas is generated in the layers formed with GaN.

Further, in the nitride semiconductor diode of any of the above described embodiments, the thickness of each of the layers formed with AlGaN is preferably 15 to 30 nm, and the thickness of each of the layers formed with GaN is preferably 50 to 300 nm.

### REFERENCE SIGNS LIST

1 first GaN layer
2 second GaN layer
3 third GaN layer
4 fourth GaN layer
5 fifth GaN layer
11 first AlGaN layer
12 second AlGaN layer
13 third AlGaN layer
14 fourth AlGaN layer
15 fifth AlGaN layer
21 sapphire substrate
22 low-temperature buffer layer
23 GaN cap layer
31 first undoped AlGaN layer with an Al composition of 0.25
32 second undoped AlGaN layer with an Al composition of 0.25
33 third undoped AlGaN layer with an Al composition of 0.25
41 anode electrode
42 cathode electrode
43 region turned into the n-type
44 SiN film
45 polyimide film
51 first n-type AlGaN layer
52 second n-type AlGaN layer
53 third n-type AlGaN layer
54 fourth n-type AlGaN layer
55 fifth n-type AlGaN layer
61 first undoped AlGaN layer
62 second undoped AlGaN layer
63 third undoped AlGaN layer
64 fourth undoped AlGaN layer
65 fifth undoped AlGaN layer
71 first n-type GaN layer
72 second n-type GaN layer
73 third n-type GaN layer
74 fourth n-type GaN layer
75 fifth n-type GaN layer
81 first undoped GaN layer
82 second undoped GaN layer
83 third undoped GaN layer
85 fourth undoped GaN layer
85 fifth undoped GaN layer
101 first 2DEG conductive layer
102 second 2DEG conductive layer
103 third 2DEG conductive layer
104 fourth 2DEG conductive layer
105 fifth 2DEG conductive layer
111, 112, 113 nitride semiconductor diode
114 large-area diode

1. A nitride semiconductor diode comprising:
a substrate;
a nitride semiconductor film stack formed on the substrate by alternately stacking a plurality of layers made of GaN as lower layers and a plurality of layers made of AlGaN as upper layers, the nitride semiconductor film stack including a plurality of conductive layers formed with a two-dimensional electron gas generated on the lower layer sides of heterojunction interfaces between the lower layers and the upper layers;
a recess formed in part of the nitride semiconductor film stack;
a cathode electrode in contact with part of the nitride semiconductor film stack, the cathode electrode being ohmically connected to the conductive layers formed with the two-dimensional electron gas; and
an anode electrode schottky-connected to a side surface of the nitride semiconductor film stack, the side surface of the nitride semiconductor film stack including side surfaces of the conductive layers formed with the two-dimensional electron gas, the side surfaces of the conductive layers being exposed through the recess, wherein
the conductive layers formed with the two-dimensional electron gas function as drift layers,
each of the layers made of AlGaN has a first stack structure formed with an n-type AlGaN layer having n-type conductivity with an impurity added thereto, and an undoped AlGaN layer not having an impurity added thereto, and,
in each of the layers made of AlGaN and formed with the first stack structures, the n-type AlGaN layer is located in a lower position than the undoped AlGaN layer.

2. A nitride semiconductor diode comprising:
a substrate;
a nitride semiconductor film stack formed on the substrate by alternately stacking a plurality of layers made of GaN as lower layers and a plurality of layers made of AlGaN as upper layers, the nitride semiconductor film stack including a plurality of conductive layers formed with a two-dimensional electron gas generated on the lower layer sides of heterojunction interfaces between the lower layers and the upper layers;
a recess formed in part of the nitride semiconductor film stack;
a cathode electrode in contact with part of the nitride semiconductor film stack, the cathode electrode being ohmically connected to the conductive layers formed with the two-dimensional electron gas; and
an anode electrode schottky-connected to a side surface of the nitride semiconductor film stack, the side surface of the nitride semiconductor film stack including side surfaces of the conductive layers formed with the two-dimensional electron gas, the side surfaces of the conductive layers being exposed through the recess, wherein
the conductive layers formed with the two-dimensional electron gas function as drift layers,
each of the layers made of GaN has a second stack structure formed with an n-type GaN layer having n-type conductivity with an impurity added thereto, and an undoped GaN layer not having an impurity added thereto, and,
in each of the layers made of GaN and formed with the second stack structures, the n-type GaN layer is located in a lower position than the undoped GaN layer.

3. A nitride semiconductor diode comprising:
a substrate;
a nitride semiconductor film stack formed on the substrate by alternately stacking a plurality of layers made of GaN as lower layers and a plurality of layers made of AlGaN as upper layers, the nitride semiconductor film stack including a plurality of conductive layers formed with a two-dimensional electron gas generated on the lower layer sides of heterojunction interfaces between the lower layers and the upper layers;
a recess formed in part of the nitride semiconductor film stack;
a cathode electrode in contact with part of the nitride semiconductor film stack, the cathode electrode being ohmically connected to the conductive layers formed with the two-dimensional electron gas; and
an anode electrode schottky-connected to a side surface of the nitride semiconductor film stack, the side surface of the nitride semiconductor film stack including side surfaces of the conductive layers formed with the two-dimensional electron gas, the side surfaces of the conductive layers being exposed through the recess, wherein
the conductive layers formed with the two-dimensional electron gas function as drift layers,
each of the layers made of AlGaN has a first stack structure formed with an n-type AlGaN layer having n-type conductivity with an impurity added thereto, and an undoped AlGaN layer not having an impurity added thereto,
in each of the layers made of AlGaN and formed with the first stack structures, the n-type AlGaN layer is located in a lower position than the undoped AlGaN layer,
each of the layers made of GaN has a second stack structure formed with an n-type GaN layer having n-type conductivity with an impurity added thereto, and an undoped GaN layer not having an impurity added thereto, and,
in each of the layers made of GaN and formed with the second stack structures, the n-type GaN layer is located in a lower position than the undoped GaN layer.

4. The nitride semiconductor diode according to claim 1, wherein a Si doping concentration of the n-type AlGaN layer is in the range of 5×10¹⁶ cm⁻³ to 5×10¹⁷ cm⁻³.

5. The nitride semiconductor diode according to claim 3, wherein a Si doping concentration of the n-type AlGaN layer is in the range of 5×10¹⁶ cm⁻³ to 5×10¹⁷ cm⁻³.

6. The nitride semiconductor diode according to claim 2, wherein a Si doping concentration of the n-type GaN layer is in the range of 5×10¹⁶ cm⁻³ to 5×10¹⁷ cm⁻³.

7. The nitride semiconductor diode according to claim 3, wherein a Si doping concentration of the n-type GaN layer is in the range of 5×10¹⁶ cm⁻³ to 5×10¹⁷ cm⁻³.

8. The nitride semiconductor diode according to claim 1, wherein an exposed nitride semiconductor surface, part of the anode electrode, and part of the cathode electrode are covered with an insulating protection film.

9. The nitride semiconductor diode according to claim 2, wherein an exposed nitride semiconductor surface, part of the anode electrode, and part of the cathode electrode are covered with an insulating protection film.

10. The nitride semiconductor diode according to claim 3, wherein an exposed nitride semiconductor surface, part of the anode electrode, and part of the cathode electrode are covered with an insulating protection film.

11. The nitride semiconductor diode according to claim 1, wherein a cap layer made of GaN is further provided as a top layer of the nitride semiconductor film stack.

12. The nitride semiconductor diode according to claim 2, wherein a cap layer made of GaN is further provided as a top layer of the nitride semiconductor film stack.

13. The nitride semiconductor diode according to claim 3, wherein a cap layer made of GaN is further provided as a top layer of the nitride semiconductor film stack.
